(19) United States
(12) Patent Application Publication
(10) Pub. No.: US 2015/0001601 A1
(43) Pub. Date: Jan. 1, 2015

(54) SPIN INJECTION ELECTRODE STRUCTURE AND SPIN TRANSPORT ELEMENT HAVING THE SAME

(71) Applicant: TDK CORPORATION, Tokyo (JP)

(72) Inventors: Hayato Koike, Tokyo (JP); Tohru Oikawa, Tokyo (JP); Tomoyuki Sasaki, Tokyo (JP)

(21) Appl. No.: 14/378,281

(22) PCT Filed: Feb. 12, 2013
(86) PCT No.: PCT/JP2013/053180

§ 371 Date: Aug. 12, 2014

(30) Foreign Application Priority Data
Feb. 14, 2012 (JP) 2012-029253

(51) Int. Cl. H01L 43/02; H01L 29/82

(52) U.S. Cl. CPC H01L 43/02; H01L 29/82
USPC 257/295

(57) ABSTRACT

To provide a spin injection electrode structure capable of injecting spins into a semiconductor with high efficiency and a spin transport element having the same. Aluminum oxide containing a γ-phase is used as a material making up a tunnel barrier layer. A protective film is formed outside the tunnel barrier layer. This allows a good spin injection electrode structure with few defects in a crystal or at a junction interface to be obtained, enables spins to be injected into a semiconductor with high efficiency, and allows a spin transport element having high output characteristics at room temperature to be provided.

### TECHNICAL FIELD

The present invention relates to a spin injection electrode structure and a spin transport element having the same.

### BACKGROUND ART

In recent years, spin transport phenomena in semiconductors have been attracting much attention. The spin diffusion length in semiconductors is far longer than the spin diffusion length in metals and therefore has superiority in various applications from the viewpoint of output and circuitry. In particular, silicon is a core material for current major semiconductor products. If silicon-based spintronics can be established, then innovative functions can be added to silicon devices without abandoning existing techniques. For example, a spin-MOSFET disclosed in Patent Literature 1 is cited.

In order to achieve a silicon-based spin transport device, sufficient output characteristics need to be obtained at room temperature. Therefore, it is essential to inject and accumulate spins into silicon with high efficiency and a multilayer structure in which a tunnel barrier layer is inserted into a ferromagnetic layer/silicon interface is expected.

Al₂O₃ (Non-Patent Literature 1), SiO₂ (Non-Patent Literature 2), and MgO (Non-Patent Literature 3) are known as materials for tunnel barrier layers and have been typical materials in spintronics. In particular, MgO is a material capable of achieving a coherent tunneling and therefore is believed to be suitable for tunnel barrier layers for efficiently injecting spins. A room-temperature spin transport phenomenon in silicon has been actually observed in a multilayer structure including a ferromagnetic layer made of Fe and a tunnel barrier layer made of MgO (Non-Patent Literature 4). However, output characteristics have not reached theoretical values. Therefore, the spin injection efficiency is expected to be further improved.

### CITATION LIST

### Patent Literature

PTL 1: Japanese Unexamined Patent Application Publication No. 2004-111904

### Non Patent Literature

NPL 1: Applied Physics Letters, Vol. 91, p. 212109, (2007)

NPL 2: Applied Physics Letters, Vol. 95, p. 172102, (2009)

NPL 3: Applied Physics Letters, Vol. 2, p. 053003, (2009)

NPL 4: Applied Physics Letters, Vol. 4, p. 023003, (2011)

### SUMMARY OF INVENTION

### Technical Problem

The lattice mismatch of a tunnel barrier layer/silicon junction is cited as a cause of a reduction in spin injection efficiency. The lattice mismatch is calculated from intrinsic parameters (lattice constants) of materials for two stacked layers. For, for example, an MgO/silicon junction, the lattice mismatch is −22.4% in the case of cubic-on-cubic growth or is +9.7% in the case of in-plane 45-degree rotation growth. The lattice mismatch is large in every case. When the lattice mismatch is large, dangling bonds remain at a junction interface and produced defect levels probably trap or scatter spins.

A material for the tunnel barrier layer is usually stable in an amorphous state and therefore it is difficult to epitaxially grow the material on silicon. Even if epitaxial growth is available, structural changes occur due to fabrication processes or usage environments in the case of lacking chemical stability. When the quality of the tunnel barrier layer is low, spins are trapped or scattered in the tunnel barrier layer, thereby causing a significant reduction in spin injection efficiency.

The present invention has been made to solve the above problems. It is an object of the present invention to provide a spin injection electrode structure capable of injecting spins into silicon with high efficiency and a spin transport element capable of suppressing the deterioration of the quality of a tunnel barrier layer.

### Solution to Problem

A spin injection electrode structure according to the present invention includes a semiconductor channel layer, a tunnel barrier layer placed on the semiconductor channel layer, and a ferromagnetic layer placed on the tunnel barrier layer. The tunnel barrier layer is made of aluminum oxide containing a γ-phase (a cubic system, a defective spinel-type crystal structure).

The tunnel barrier layer has a thickness of 0.6 nm to 2.0 nm.

A spin transport element according to the present invention includes a spin injection electrode having the spin injection electrode structure, a semiconductor channel layer in which injected or accumulated spins are diffused or transported, and a spin detection electrode detecting the diffused or transported spins.

A protective film made of a chemically inert insulating material is placed over side walls of the spin injection and detection electrodes and covers an outer portion of a tunnel barrier layer and an outer portion of a ferromagnetic layer.

### Advantageous Effects of Invention

According to the present invention, the following structure can be obtained: a spin injection electrode structure which have few defects at a junction interface and which includes a tunnel barrier layer with good crystallinity. This enables spins to be injected into a semiconductor channel with high efficiency and allows a spin transport element having high output characteristics at room temperature to be provided.

### BRIEF DESCRIPTION OF DRAWINGS

FIG. 1 is a perspective view of a spin transport element according to this embodiment.

FIG. 2 is a sectional view taken along the line III-III of FIG. 1.

FIG. 3 is a graph showing the relationship between the intensity (Oe) of a magnetic field B1 applied in a Y-axis direction and the voltage output (μV) detected accordingly in non-local spin valve measurement.

FIG. 4 is a graph showing the relationship between the intensity (Oe) of a magnetic field B2 applied in a Z-axis direction and the voltage output (μV) detected accordingly in the non-local Hanle measurement.

### DESCRIPTION OF EMBODIMENTS

Embodiments of the present invention will now be described in detail with reference to the accompanying drawings. In the description of the drawings, the same components are given the same reference numerals and will not be described redundantly.

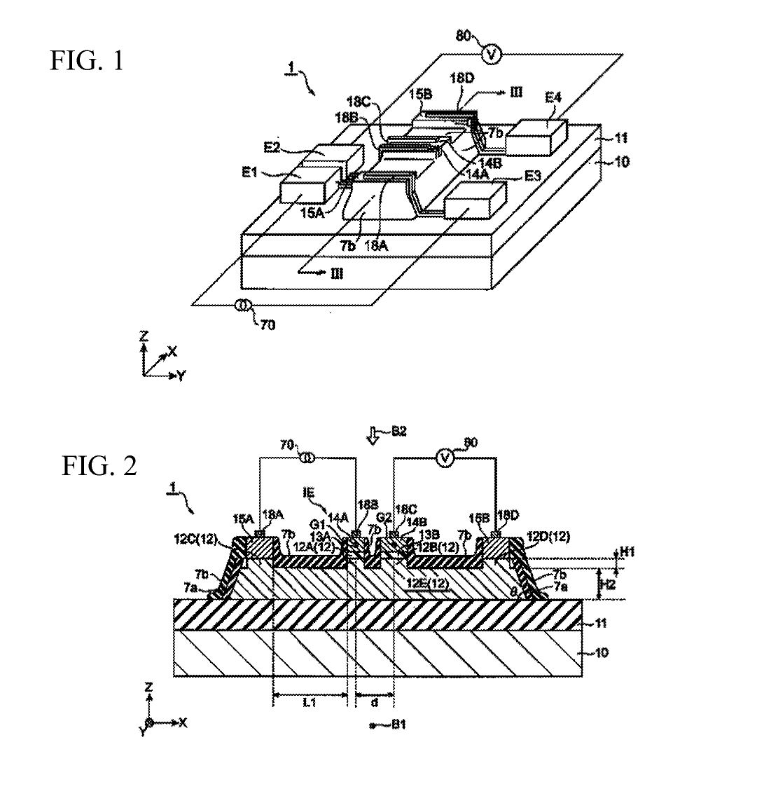

FIG. 1 is a perspective view of a spin transport element 1. FIG. 2 is a sectional view taken along the line III-III of FIG. 1.

As shown in FIG. 2, in the case of using silicon as a semiconductor, the spin transport element 1 includes a silicon oxide film 11 and silicon channel layer 12 placed on a silicon substrate 10 in that order. The silicon channel layer 12 is overlaid with a first non-magnetic electrode 15A, first ferromagnetic layer 14A, second ferromagnetic layer 14B, and second non-magnetic electrode 15B which are arranged at predetermined intervals in an X-axis direction in that order. A tunnel barrier layer 13A is placed between the silicon channel layer 12 and the first ferromagnetic layer 14A and a tunnel barrier layer 13B is placed between the silicon channel layer 12 and the second ferromagnetic layer 14B. The silicon channel layer 12, the tunnel barrier layer 13A, and the first ferromagnetic layer 14A form a spin injection electrode structure IE.

For example, an SOT (silicon-on-insulator) wafer can be used as the silicon substrate 10, the silicon oxide film 11, and the silicon channel layer 12. The silicon oxide film 11 has a thickness of, for example, 200 nm.

The silicon channel layer 12 used is one doped with a dopant for imparting conductivity to silicon. The concentration of the dopant may be 1.0×10¹⁶ cm⁻³ to 1.0×10²² cm⁻³. The silicon channel layer 12 has a thickness of, for example, 100 nm. The silicon channel layer 12 may be a multilayer channel delta-doped at a predetermined concentration. Unlike doping in which a dopant is homogeneously distributed, delta doping means that an extremely thin region extending from an interface by about several nanometers is doped at a high dopant concentration.

As shown in FIG. 2, the silicon channel layer 12 has side surfaces having sloped sections which have an inclination θ of 50 degrees to 60 degrees. The inclination θ refers to the angle formed by the bottom and a side surface of the silicon channel layer 12. The silicon channel layer 12 can be formed by wet etching. The upper surface of the silicon channel layer 12 is preferably oriented in the (100) plane.

As shown in FIG. 2, the silicon channel layer 12 includes a first convex section 12A, a second convex section 12B, a third convex section 12C, a fourth convex section 12D, and a principal section 12E. The first convex section 12A, the second convex section 12B, the third convex section 12C, and the fourth convex section 12D are extending sections protruding from the principal section 12E and are arranged at predetermined intervals in the X-axis direction in that order.

The first convex section 12A, the second convex section 12B, the third convex section 12C, and the fourth convex section 12D have a thickness H1 of, for example, 20 nm. The principal section 12E has a thickness H2 of, for example, 80 nm. The distance L1 between the first convex section 12A and the third convex section 12C is, for example, 100 μm or less. The distance d between a longitudinal central portion of the first convex section 12A in the X-axis direction and a longitudinal central portion of the second convex section 12B in the X-axis direction is preferably less than or equal to the spin diffusion length. The spin diffusion length of the silicon channel layer 12 is about 0.8 μm at room temperature (300 K).

The tunnel barrier layers 13A and 13B are made of aluminum oxide containing a γ-phase (a cubic system, a defective spinel-type crystal structure) and are epitaxially grown on the first convex section 12A and second convex section 12B of the silicon channel layer. Since the lattice constant (a) of the γ-Al₂O₃ is 7.91 Å, the lattice mismatch to silicon (a=5.43 Å) is +3.0% (45-degree rotation). This allows a multilayer structure having few defect levels present at a junction interface to be obtained. Therefore, the trapping and scattering of spins at the junction interface can be suppressed.

The thickness of the tunnel barrier layers 13A and 13B is preferably 2.0 nm or less. This allows a good epitaxial film with few crystal defects (misfit dislocations) to be obtained. Therefore, a coherent tunnel can be achieved. In addition, the thickness of the tunnel barrier layers 13A and 13B is preferably 0.6 nm or more in consideration of the thickness of a monoatomic layer. When the thickness is less than 0.6 nm, which is less than or equal to the lattice constant, the film quality and the dielectric strength are insufficient and therefore pinholes are likely to be caused. This is not preferred in view of reliability. When the thickness is more than 2.0 nm, the element resistance is excessively high. Therefore, only a slight charge current can flow and only a small number of spins can be injected. This is not practical.

One of the first ferromagnetic layer 14A and the second ferromagnetic layer 14B functions as an electrode for injecting spins into the silicon channel layer 12 and the other functions as an electrode for detecting spins transported in the silicon channel layer 12. The first ferromagnetic layer 14A is placed on the tunnel barrier layer 13A. The second ferromagnetic layer 14B is placed on the tunnel barrier layer 13B.

The first ferromagnetic layer 14A and the second ferromagnetic layer 14B are made of at least one selected from the group consisting of Mn, Co, Fe, and Ni as a primary component. These materials are ferromagnetic materials with high spin polarization and therefore can preferably achieve a function as a spin injection electrode or a spin detection electrode.

The first ferromagnetic layer 14A and the second ferromagnetic layer 14B preferably have a crystal structure such as a body-centered cubic (bcc) structure and may include a sub-layer made of a Heusler alloy. This allows the ferromagnetic layers to be epitaxially grown on the tunnel barrier layers in a predetermined orientation and therefore enables the spin polarization to be further increased.

The first ferromagnetic layer 14A and the second ferromagnetic layer 14B preferably have a difference in coercive force (magnetic switching field). In an example shown in FIG. 1, the first ferromagnetic layer 14A and the second ferromagnetic layer 14B have a rectangular parallelepiped shape elongated in a Y-axis direction and have a difference in coercive force due to shape anisotropy (difference in aspect ratio). The width (length in the X-axis direction) of the first ferromagnetic layer 14A is, for example, about 350 nm. The width (length in the X-axis direction) of the second ferromagnetic layer 14B is, for example, about 2 μm.

One of the first ferromagnetic layer 14A and the second ferromagnetic layer 14B may include an antiferromagnetic sub-layer such that the magnetization of one of the ferromagnetic layers is pinned in one direction. Furthermore, the exchange coupling with the antiferromagnetic sub-layer may be enhanced with a synthetic pinned structure. The magnetization of the ferromagnetic layers may be oriented in one direction in such a way that a bias magnetic field-applying layer is provided next thereto.

One of the first non-magnetic electrode 15A and the second non-magnetic electrode 15B functions as an electrode for injecting a spin-polarized current into the silicon channel layer 12 and the other functions as an electrode for detecting spins transported in the silicon channel layer 12. The first non-magnetic electrode 15A and the second non-magnetic electrode 15B are placed on the third convex section 12C and fourth convex section 12D, respectively, of the silicon channel layer 12. The first non-magnetic electrode 15A and the second non-magnetic electrode 15B are made of, for example, a non-magnetic metal, such as Al, having lower resistivity compared to Si.

A protective film 7a is placed over side surfaces of the silicon channel layer 12. A protective film 7b is placed over side surfaces of the silicon channel layer 12, the protective film 7a, the tunnel barrier layer 13A, the tunnel barrier layer 13B, the first ferromagnetic layer 14A, the second ferromagnetic layer 14B, the first non-magnetic electrode 15A, and the second non-magnetic electrode 15B. The protective film 7b is placed on the principal portion Principal section 12E, that is, the upper surface of the silicon channel layer 12 that is not covered by the first ferromagnetic layer 14A, the second ferromagnetic layer 14B, the first non-magnetic electrode 15A, or the second non-magnetic electrode 15B. The protective films 7a and 7b are placed so as to insulate the silicon channel layer 12 and so as to suppress the absorption of spins by wiring lines. The protective films 7a and 7b function as protectors for preventing the tunnel barrier layers 13A and 13B, which lacks chemical stability, from being exposed to outside to suppress the change and deterioration in characteristics of the spin transport element 1. The protective films 7a and 7b are made of, for example, SiO₂.

As shown in FIG. 1, wiring lines 18A, 18B, 18C, and 18D are placed on the first non-magnetic electrode 15A, the first ferromagnetic layer 14A, the second ferromagnetic layer 14B, and the second non-magnetic electrode 15B, respectively, and are routed on the protective film 7b (sloped side surfaces of the silicon channel layer 12) to the silicon oxide film 11. The wiring lines 18A, 18B, 18C, and 18D are made of, for example, a low-resistance conductive material such as Cu.

As shown in FIG. 1, each of electrode pads E1, E2, E3, and E4 is connected to a corresponding one of end portions of the wiring lines 18A, 18B, 18C, and 18D and is placed on the silicon oxide film 11. The electrode pads E1, E2, E3, and E4 are made of for example, a low-resistance conductive material, such as Au, having high corrosion resistance.

An example of the operation of the spin transport element 1 according to an embodiment of the present invention is described below.

As shown in FIGS. 1 and 2, when the electrode pads E1 and E3 are connected to a current source 70, a spin-polarized current corresponding to the magnetization direction G1 of the first ferromagnetic layer 14A flows through the first ferromagnetic layer 14A, the tunnel barrier layer 13A, the silicon channel layer 12, and the first non-magnetic electrode 15A. Spins corresponding to the magnetization direction G1 of the first ferromagnetic layer 14A are accordingly injected into the silicon channel layer 12 to diffuse to the second ferromagnetic layer 14B in the form of a spin current. That is, a structure in which a spin current and a charge current flow through the silicon channel layer 12 in the X-axis direction can be obtained.

Spins injected from the first ferromagnetic layer 14A into the silicon channel layer 12 to diffuse to the second ferromagnetic layer 14B generate a voltage output at the interface between the silicon channel layer 12 and the second ferromagnetic layer 14B because of the difference in potential from spins corresponding to the magnetization direction G2 of the second ferromagnetic layer 14B. The voltage output can be detected in such a way that the electrode pads E2 and E4 are connected to an output-measuring instrument 80 as shown in FIGS. 1 and 2.

Herein, suppose the case of applying an external magnetic field B1 in the Y-axis direction as shown in FIG. 2. In this case, a so-called non-local spin valve effect can be used. Since the first ferromagnetic layer 14A and the second ferromagnetic layer 14B have a difference in coercive force (magnetic switching field) due to shape anisotropy or the like, the magnetization directions G1 and G2 thereof vary depending on the direction and intensity of the external magnetic field B1. This varies the relative angle between the spins injected from the first ferromagnetic layer 14A into the silicon channel layer 12 to diffuse to the second ferromagnetic layer 14B and the spins corresponding to the magnetization direction G2 of the second ferromagnetic layer 14B. The voltage output (resistance) at the interface between the silicon channel layer 12 and the second ferromagnetic layer 14B varies accordingly.

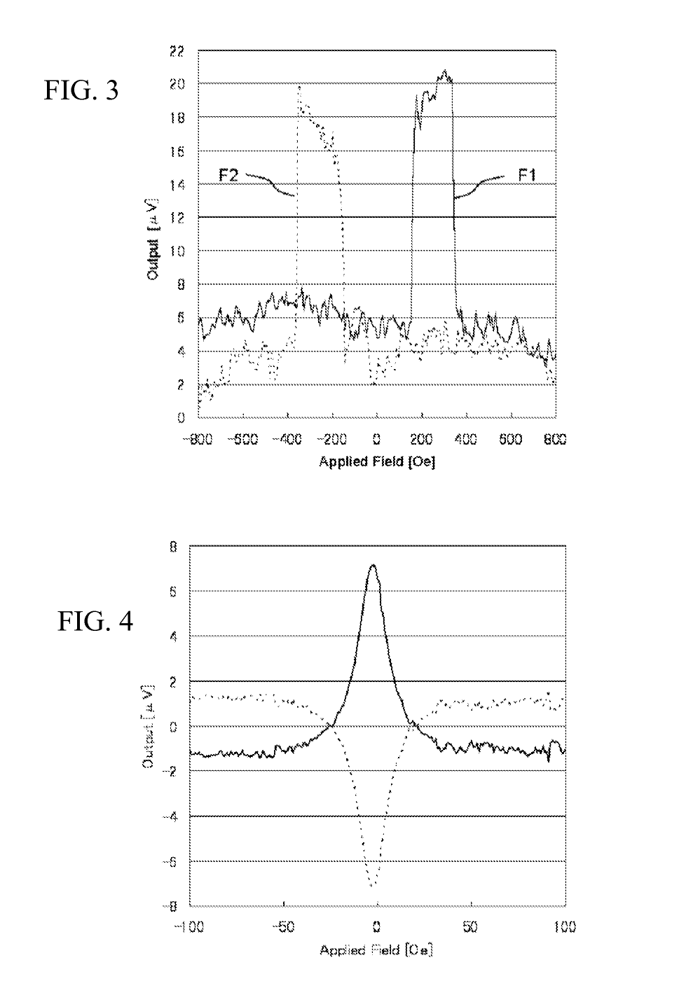

FIG. 3 shows exemplary results of non-local spin valve measurement. FIG. 3 is a graph showing the relationship between the intensity (Oe) of the magnetic field B1 applied in the Y-axis direction and the voltage output (μV) detected accordingly. In FIG. 3, F1 indicates the case of varying the external magnetic field B1 from a negative side to a positive side and F2 indicates the case of varying the external magnetic field B1 from a positive side to a negative side. That is, when the magnetization direction G1 of the first ferromagnetic layer 14A and the magnetization direction G2 of the second ferromagnetic layer 14B are parallel or antiparallel to each other, the resistance is low or high, respectively.

Next, suppose the case of applying an external magnetic field B2 in a Z-axis direction as shown in FIG. 2. In this case, a so-called non-local Hanle effect can be used. When the spins injected from the first ferromagnetic layer 14A into the silicon channel layer 12 diffuse to the second ferromagnetic layer 14B, Larmor precession occurs depending on the intensity of the external magnetic field B2 in the Z-axis direction (perpendicular to the direction of spins). This varies the relative angle between the spins injected from the first ferromagnetic layer 14A into the silicon channel layer 12 to diffuse to the second ferromagnetic layer 14B while being Larmor-rotated and the spins corresponding to the magnetization direction G2 of the second ferromagnetic layer 14B. The voltage output (resistance) at the interface between the silicon channel layer 12 and the second ferromagnetic layer 14B varies accordingly.

FIG. 4 shows exemplary results of the non-local Hanle measurement. FIG. 4 is a graph showing the relationship between the intensity (Oe) of the magnetic field B2 applied in the Z-axis direction and the voltage output (μV) detected accordingly. When the external magnetic field is zero, spins diffusing in the silicon channel layer 12 are not Larmor-rotated and the state of the injected spins is maintained. Therefore, the voltage output is an extremum. That is, when the magnetization direction G1 of the first ferromagnetic layer 14A and the magnetization direction G2 of the second ferromagnetic layer 14B are parallel to each other, the resistance increases with the increase in intensity of the magnetic field. When the magnetization direction G1 of the first ferromagnetic layer 14A and the magnetization direction G2 of the second ferromagnetic layer 14B are antiparallel to each other, the resistance decreases with the increase in intensity of the magnetic field.

While embodiments of the present invention have been described above in detail, the present invention is not limited to the embodiments. The semiconductor channel layer may be made of, for example, GaAs (a=5.65 Å) or Ge (a=5.67 Å). The lattice mismatch to γ-Al₂O₃ is −1.0% or −1.4% and therefore effects similar to those of the present invention can be obtained.

Furthermore, a gate electrode may be placed above the silicon channel layer 12 so as to be located between the first ferromagnetic layer 14A and the second ferromagnetic layer 14B. This allows the rotation angle of spins transported in the silicon channel layer 12 to be controlled with the gate electrode.

The use of the above-mentioned operation allows the spin transport element 1 according to the present invention to be applied to, for example, various spin transport devices such as magnetic heads, magnetoresistive random access memories (MRAMs), logic circuits, nuclear spin memories, and quantum computers.

### EXAMPLES

The present invention is further described below in detail on the basis of Example 1, Comparative Example 1, and Comparative Example 2. The present invention is not limited to examples below.

### Example 1

An SOT wafer including a silicon substrate, a silicon oxide film (a thickness of 200 nm), and a silicon film (a thickness of 100 nm) was prepared. A dopant for imparting conductivity to the silicon film was ion-implanted into the silicon film, was diffused, and was activated by annealing at 900° C., whereby a homogeneously doped silicon channel layer with a carrier concentration of 5.0×10¹⁹ cm⁻³ was formed.

Next, deposits, organic matter, and native oxides were removed from surfaces of the SOI wafer by RCA cleaning. The surfaces of the SOI wafer were terminated with hydrogen. Subsequently, the SOI wafer was flashed in molecular beam epitaxy (MBE) system, whereby the surfaces of the SOI wafer were cleaned and were planarized.

Next, Al₂O₃ (a thickness of 0.8 nm) as a tunnel barrier layer, Fe (a thickness of 13 nm) as a ferromagnetic layer, and Ti (a thickness of 3 nm) as an anti-oxidation film for Fe were deposited on the SOI wafer by MBE in that order, whereby a stack was formed. Evaluation subsequent to deposition confirmed that Al₂O₃ contained a γ-phase (a cubic system, a defective spinel-type crystal structure) and were epitaxially grown on Si. Incidentally, in the evaluation subsequent to deposition, the crystal structure of the tunnel barrier layer and the crystal orientation of the deposited film were evaluated by X-ray diffractometry (XRD) and high-resolution transmission electron microscopy (HRTEM), respectively.

Next, the stack was patterned by photolithography and ion milling, whereby the silicon channel layer was exposed. The silicon channel layer was anisotropically wet-etched using the stack and a resist as masks, whereby the silicon channel layer was shaped so as to have side surfaces having sloped sections. In this operation, the silicon channel layer was sized to 23 μm×300 μm and the side surfaces of the silicon channel layer were oxidized.

Next, the stack was patterned by photolithography and ion milling, whereby a spin injection electrode and a spin detection electrode were formed. Furthermore, SiO₂ as a protective film was deposited on side walls of the spin injection and detection electrodes and an exposed portion of the silicon channel layer. Thereafter, locations used to form a first non-magnetic electrode and a second non-magnetic electrode were removed from the protective film and the first and second non-magnetic electrodes were formed using Al.

Next, each of wiring lines was formed on a corresponding one of the spin injection electrode, the spin detection electrode, the first non-magnetic electrode, and the second non-magnetic electrode. Multilayer structures of Ta (a thickness of 10 nm), Cu (a thickness of 50 nm), and Ta (a thickness of 10 nm) were used as the wiring lines. Furthermore, each of electrode pads was formed on an end portion of a corresponding one of the wiring lines. Multilayer structures of Cr (a thickness of 50 nm) and Au (a thickness of 150 nm) were used as the electrode pads. As described above, a spin transport element having substantially the same configuration as that of the spin transport element 1 shown in FIGS. 1 and 2 was prepared in Example 1.

### Comparative Example 1

In Comparative Example 1, a spin transport element was prepared by substantially the same procedure as that described in Example 1 except that conditions for forming the tunnel barrier layer described in Example 1 were varied. After deposition, the same evaluation as that described in Example 1 confirmed that Al₂O₃ was amorphous.

### Comparative Example 2

In Comparative Example 2, a spin transport element was prepared by substantially the same procedure as that described in Example 1 except that the tunnel barrier layer described in Example 1 was formed using MgO (a thickness of 0.8 nm). After deposition, the same evaluation as that described in Example 1 confirmed that MgO had a cubic crystal structure (NaCl-type structure) and was epitaxially grown. It was observed that lattice defects probably due to lattice mismatch were present at the interface between the tunnel barrier layer and a silicon channel layer.

These spin transport elements were subjected to non-local spin valve measurement at room temperature. Detected voltage outputs were summarized in Table 1. The voltage output of each sample was normalized on the basis of the voltage output obtained in Comparative Example 2 (MgO). The lattice mismatch (%) of a tunnel barrier layer/silicon junction was also specified.

TABLE 1

| | Tunnel barrier | Lattice | Voltage output |
|---|---|---|---|
| Sample | layer | mismatch (%) | (normalized) |
| Example 1 | Crystalline | +3.0 | 2.32 |
| | Al₂O₃ (γ-phase) | | |
| Comparative | Amorphous Al₂O₃ | | Undetectable |
| Example 1 | | | |
| Comparative | Crystalline MgO | −9.7 | 1.00 |
| Example 2 | | | |

As shown in Table 1, in Comparative Example 1, spin transport could not be observed at room temperature. This is probably because spins are trapped or scattered in the tunnel barrier layer because of the irregularity of an amorphous atomic arrangement. In Comparative Example 2 (MgO) and Example 1 (γ-Al₂O₃), spin transport could be observed at room temperature. In Example 1, a voltage output two times or more that observed in Comparative Example 2 was observed. This shows that spins can probably be injected into silicon with high efficiency in such a way that the lattice mismatch of a tunnel barrier layer/silicon junction is reduced and a spin injection electrode structure with few defects at a junction interface is formed.

In the above example, the ferromagnetic layer was limited to Fe for the purpose of making systematic comparisons independent of materials. It is needless to describe that changing a material for the ferromagnetic layer is effective in reducing the lattice mismatch at the interface between the ferromagnetic layer and the tunnel barrier layer.

### REFERENCE SIGNS LIST

IE Spin injection electrode structure

1 Spin transport element

10 Substrate

11 Silicon oxide film

12 Silicon channel layer

13A, 13B Tunnel barrier layer

14A First ferromagnetic layer

14B Second ferromagnetic layer

15A First non-magnetic electrode

15B Second non-magnetic electrode

70 Current source

80 Output-measuring instrument

1. A spin injection electrode structure comprising a semiconductor channel layer, a tunnel barrier layer placed on the semiconductor channel layer, and a ferromagnetic layer placed on the tunnel barrier layer, wherein the tunnel barrier layer is made of aluminum oxide containing a γ-phase (a cubic system, a defective spinel-type crystal structure).

2. The spin injection electrode structure according to claim 1, wherein the tunnel barrier layer has a thickness of 0.6 nm to 2.0 nm.

3. A spin transport element comprising a spin injection electrode having the spin injection electrode structure according to claim 1, a semiconductor channel layer, and a spin detection electrode detecting spins.

4. The spin transport element according to claim 3, comprising a protective film placed over side walls of the spin injection and detection electrodes.
